(19) United States
(12) Patent Application Publication
(10) Pub. No.: US 2008/0224698 A1
(43) Pub. Date: Sep. 18, 2008

(54) MAGNETIC RESONANCE IMAGING APPARATUS AND MAGNETIC RESONANCE IMAGING METHOD

(76) Inventor: Kenichi Kanda, Tokyo (JP)

Correspondence Address: Patrick W. Rasche;Armstrong Teasdale LLP, Suite 2600, One Metropolitan Square, St. Louis, MO, 63102, US

(21) Appl. No.: 12/046,180

(22) Filed: Mar. 11, 2008

(30) Foreign Application Priority Data
Mar. 15, 2007 (JP) 2007-067430

(51) Int. Cl. G01R 33/483

(52) U.S. Cl. 324/309

(57) ABSTRACT

A magnetic resonance imaging apparatus which executes a mask scan for acquiring, as mask data, magnetic resonance signals produced in an imaging area in which a fluid flows through a subject, in a state in which a contrast agent is not injected into the fluid, and an imaging scan for acquiring, as imaging data, magnetic resonance signals produced in the imaging area in which the fluid containing the contrast agent flows after the injection of the contrast agent into the fluid, so as to correspond to a TRICKS method, thereby sequentially generating images about the imaging area along a time base, said magnetic resonance imaging apparatus includes
a scan device which executes the mask scan and the imaging scan, wherein upon execution of the mask scan, the scan device repeatedly executes scans for transmitting a spatial saturation pulse to a corresponding area containing the fluid flowing into the imaging area and thereafter sequentially acquiring the magnetic resonance signals as the mask data every time of repetition, so as to correspond to respective segments divided into plural form in a k space.

### BACKGROUND OF THE INVENTION

The present invention relates to a magnetic resonance imaging (MRI) apparatus and a magnetic resonance imaging method. The present invention relates particularly to a magnetic resonance imaging apparatus and a magnetic resonance imaging method each of which executes a mask scan for acquiring magnetic resonance signals produced in an imaging area of a subject as mask data, and an imaging scan for acquiring magnetic resonance signals produced in the imaging area as imaging data, so as to correspond to a TRICKS (Time Resolved Imaging for Contrast KineticS) method, thereby sequentially generating images about the imaging area along a time base.

The magnetic resonance imaging apparatus has been used in various fields such as a medical field, an industrial field, etc.

The magnetic resonance imaging apparatus includes an imaging space formed with a static magnetic field. An imaging area including a target for imaging at a subject is accommodated or held in the imaging space. Thus, spins of proton in the imaging area are arranged in the direction in which the static magnetic field is formed, to obtain magnetization vectors thereof. Thereafter, an RF pulse is transmitted to the imaging area of the subject in the imaging space formed with the static magnetic field to generate a nuclear magnetic resonance (NMR) phenomenon, thereby flipping the magnetization vectors of the spins. Then, magnetic resonance (MR) signals generated when the magnetization vectors of the flipped spins are returned in an original static magnetic-field direction, are acquired. The subject is scanned in accordance with, for example, a pulse sequence such as a spin echo method, a gradient recalled echo method or the like. Then, image reconstruction processing is effected on magnetic resonance signals acquired by execution of this scan to generate slice images about an imaging area of the subject.

In the magnetic resonance imaging apparatus, blood imaging called “MRA (MR angiography)” is executed to project or create a fluid such as the blood flowing through blood vessels. In this MA, imaging is carried out using a time of flight (TOF) effect or a phase contrast (PC) effect or the like.

As an imaging method for this MRA, a TRICKS method has been proposed (refer to, for example, a patent document 1 and a patent document 2). Since imaging can be carried out by a simple operation and high time resolution can be provided in the present method, each slice image can be obtained with suitable timing with respect to an imaging area in which a contrast agent has flowed. The TRICKS method is useful because each imaging area containing portions which vary in arrival time of the contrast agent and are difficult to take exact timing as in the case of peripheral blood vessels of human lower limbs and the like, can be imaged or photographed continuously in a short period of time.

Patent Document 1. Japanese Unexamined Patent Publication No. Hei 10 (1998)-5191.

Patent Document 2. Japanese Unexamined Patent Publication No. 2006-122301.

In the TRICKS method, however, each magnetic signal acquired as the mask data might be a high signal at each portion in which the fluid such as the blood flows, due to the influence of an in-flow effect upon acquisition of the mask data by the first gradient echo method. Therefore, when image data about a mask image MG generated based on such mask data is subtracted from image data about each imaging image IG, a portion in which the contrast agent flows may not be generated high in contrast at each different image SG. Therefore, image quality is deteriorated and efficient execution of an image diagnosis may fall into difficulties.

### SUMMARY OF THE INVENTION

It is desirable that the problem described previously is solved.

In one aspect of the invention, there is provided a magnetic resonance imaging apparatus which executes a mask scan for acquiring, as mask data, magnetic resonance signals produced in an imaging area in which a fluid flows through a subject, in a state in which a contrast agent is not injected into the fluid, and an imaging scan for acquiring, as imaging data, magnetic resonance signals produced in the imaging area in which the fluid containing the contrast agent flows after the injection of the contrast agent into the fluid, so as to correspond to a TRICKS method, thereby sequentially generating images about the imaging area along a time base, the magnetic resonance imaging apparatus comprising a scan device which executes the mask scan and the imaging scan, wherein upon execution of the mask scan, the scan device repeatedly executes scans for transmitting a spatial saturation pulse to a corresponding area containing the fluid flowing into the imaging area and thereafter sequentially acquiring the magnetic resonance signals as the mask data every time of repetition, so as to correspond to respective segments divided into plural form in a k space.

Preferably, the scan device executes the mask scan in such a manner that the directions of sequentially acquiring the magnetic resonance signals with respect to the respective segments as the mask data every time of repetition are faced in directions opposite to each other through the center of the k space at the segments.

Preferably, the scan device executes the mask scan in such a manner that the acquisition directions are faced from the center of the k space to its periphery.

Preferably, after the transmission of the spatial saturation pulse, the scan device further executes the mask scan so as to sequentially acquire the magnetic resonance signals as the mask data every time of repetition after the elapse of each time of repetition free of acquisition of the magnetic resonance signals as the mask data.

Preferably, upon execution of the mask scan, the scan device executes the scans in such a manner that they correspond to respective segments divided into plural form so as to be symmetric through an axis passing through the center of a k space.

Preferably, upon execution of the mask scan, the scan device executes the scans in such a manner that they correspond to respective segments divided into plural form so as to be radially symmetric from the center of a k space to its periphery.

Preferably, the scan device executes the mask scan before the execution of the imaging scan.

In another aspect of the invention, there is provided a magnetic resonance imaging method which executes a mask scan for acquiring, as mask data, magnetic resonance signals produced in an imaging area in which a fluid flows through a subject, in a state in which a contrast agent is not injected into the fluid, and an imaging scan for acquiring, as imaging data, magnetic resonance signals produced in the imaging area in which the fluid containing the contrast agent flows after the injection of the contrast agent into the fluid, so as to correspond to a TRICKS method, thereby sequentially generating images about the imaging area along a time base, the magnetic resonance imaging apparatus comprising the following step: upon execution of the mask scan, repeatedly executing scans for transmitting a spatial saturation pulse to a corresponding area containing the fluid flowing into the imaging area and thereafter sequentially acquiring the magnetic resonance signals as the mask data every time of repetition, so as to correspond to respective segments divided into plural form in a k space.

Preferably, the mask scan is carried out in such a manner that the directions of sequentially acquiring the magnetic resonance signals with respect to the respective segments as the mask data every time of repetition are faced in directions opposite to each other through the center of the k space at the segments.

Preferably, the mask scan is executed in such a manner that the acquisition directions are faced from the center of the k space to its periphery.

Preferably, after the transmission of the spatial saturation pulse, the scam section executes the mask scan so as to sequentially acquire the magnetic resonance signals as the mask data every time of repetition after the elapse of each time of repetition free of acquisition of the magnetic resonance signals as the mask data.

Preferably, upon execution of the mask scan, the scans are executed in such a manner that they correspond to respective segments divided into plural form so as to be symmetric through an axis passing through the center of a k space.

Preferably, upon execution of the mask scan, the scan device executes the scans in such a manner that they correspond to respective segments divided into plural form so as to be radially symmetric from the center of a k space to its periphery.

Preferably, the scan device executes the mask scan before the execution of the imaging scan.

In another aspect of the invention, there is provided a magnetic resonance imaging apparatus which executes a mask scan for acquiring, as mask data, magnetic resonance signals produced in an imaging area of a subject, and an imaging scan for acquiring, as imaging data, magnetic resonance signals produced in the imaging area, so as to correspond to a TRICKS method, thereby sequentially generating images about the imaging area along a time base, the magnetic resonance imaging apparatus comprising a scan device which executes the mask scan and the imaging scan, wherein upon execution of the mask scan, the scan device repeatedly executes scans for transmitting a preparation pulse to the subject and thereafter sequentially acquiring the magnetic resonance signals as the mask data every time of repetition, so as to correspond to respective segments divided into plural form in a k space.

Preferably, the scan device executes the mask scan in such a manner that the directions of sequentially acquiring the magnetic resonance signals with respect to the respective segments as the mask data every time of repetition are faced in directions opposite to each other through the center of the k space at the segments.

Preferably, the scan device executes the mask scan in such a manner that the acquisition directions are faced from the center of the k space to its periphery.

Preferably, there is provided a magnetic resonance imaging method which executes a mask scan for acquiring, as mask data, magnetic resonance signals produced in an imaging area of a subject, and an imaging scan for acquiring, as imaging data, magnetic resonance signals produced in the imaging area, so as to correspond to a TRICKS method, thereby sequentially generating images about the imaging area along a time base, the magnetic resonance imaging method comprising the following step of upon execution of the mask scan, repeatedly executing scans for transmitting a preparation pulse to the subject and thereafter sequentially acquiring the magnetic resonance signals as the mask data every time of repetition, so as to correspond to respective segments divided into plural form in a k space.

Preferably, the scan device executes the mask scan in such a manner that the directions of sequentially acquiring the magnetic resonance signals with respect to the respective segments as the mask data every time of repetition are faced in directions opposite to each other through the center of the k space at the segments.

Preferably, the scan device executes the mask scan in such a manner that the acquisition directions are faced from the center of the k space to its periphery.

Effects of the Invention. According to the invention, a magnetic resonance imaging apparatus and a magnetic resonance imaging method can be provided which are capable of enhancing image quality and carrying out an image diagnosis efficiently.

Further objects and advantages of the present invention will be apparent from the following description of the preferred embodiments of the invention as illustrated in the accompanying drawings.

### BRIEF DESCRIPTION OF THE DRAWINGS

FIG. 1 is a configuration diagram showing a construction of a magnetic resonance imaging apparatus 1 illustrative of a first embodiment according to the invention.

FIG. 2 is a flowchart showing operation taken when a subject SU is imaged or photographed in the first embodiment according to the invention.

FIG. 3 is a diagram illustrating the manner in which an imaging area of a subject is scanned by a TRICKS method in the first embodiment according to the invention, and FIG. 3 shows a time base as a horizontal axis.

FIG. 4 is a diagram showing a k space in which magnetic resonance signals are acquired or collected by execution of a mask scan MS in the first embodiment according to the present embodiment.

FIG. 5 is a pulse sequence diagram at the time that mask data are acquired every segment upon execution of the mask scan MS in the first embodiment according to the invention.

FIG. 6 is a diagram showing a sequence at the time that mask data are acquired with respect to matrices constituting segments upon execution of the mask scan MS in the first embodiment according to the invention.

FIG. 7 is a diagram illustrating a k space in which magnetic resonance signals are acquired upon execution of an imaging scan IS in the first embodiment according to the invention.

FIG. 8 is a pulse sequence at the time that imaging data are acquired every segment area upon execution of the imaging scan IS in the first embodiment according to the invention.

FIG. 9 is a flowchart showing the operation of sequentially generating images about an imaging area along a time base in the first embodiment according to the invention.

FIG. 10 is a diagram showing the manner in which a mask image MG is generated in the first embodiment according to the invention.

FIG. 11 is a diagram illustrating the manner in which each imaging image IG is generated in the first embodiment according to the invention.

FIG. 12 is a diagram depicting the manner in which each difference image SG is generated in the first embodiment according to the invention.

FIG. 13 is a diagram showing a k space in which magnetic resonance signals are acquired upon execution of a mask scan MS in a second embodiment according to the invention.

FIG. 14 is a diagram showing a k space in which magnetic resonance signals are acquired upon execution of a mask scan MS in a third embodiment according to the invention.

FIG. 15 is a diagram illustrating a sequence at the time that mask data are acquired with respect to matrices constituting segments upon execution of a mask scan MS in a fourth embodiment according to the invention.

FIG. 16 is a diagram showing a sequence at the time that mask data are acquired with respect to matrices constituting segments upon execution of a mask scan MS in a fifth embodiment according to the invention.

### DETAILED DESCRIPTION OF THE INVENTION

One example of an embodiment according to the invention will be explained below with reference to the accompanying drawings.

### First Embodiment

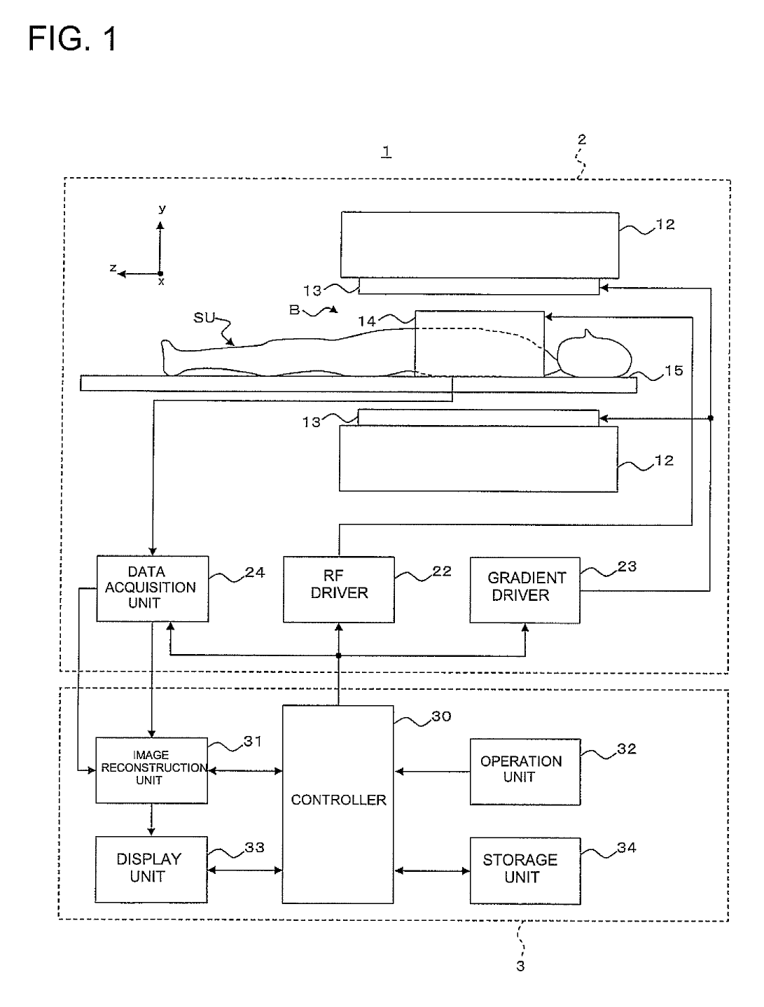

FIG. 1 is a configuration diagram showing an outline of a construction of a magnetic resonance imaging apparatus 1 illustrative of a first embodiment according to the invention.

Apparatus construction. FIG. 1 is a configuration diagram showing the construction of the magnetic resonance imaging apparatus 1 illustrative of the first embodiment according to the invention.

As shown in FIG. 1, the magnetic resonance imaging apparatus 1 has a scan section 2 and an operation console section 3.

Here, the scan section 2 has a static magnetic field magnet unit 12, a gradient coil unit 13, an RF coil unit or part 14, a cradle 15, an RF driver 22, a gradient driver 23 and a data acquisition unit 24 as shown in FIG. 1. As shown in FIG. 1, the operation console section 3 has a controller 30, an image reconstruction unit 31, an operation unit 32, a display or display unit 33 and a storage unit 34.

In the present embodiment, the magnetic resonance imaging apparatus 1 performs each scan on an imaging area of a subject so as to correspond to a TRICKS method thereby to sequentially generate images about the imaging area along a time base. That is, a mask scan for collecting or acquiring, as mask data, magnetic resonance signals produced in an imaging area in which a fluid such as the blood flows through a subject SU, in a state in which no contrast agent is injected into the fluid, and an imaging scan for acquiring, as imaging data, magnetic resonance signals produced in the imaging area in which a fluid containing the contrast agent flows, after the injection of the contrast agent into the fluid such as the blood are executed based on the TRICKS method to thereby generate images about the imaging area sequentially.

The scan section 2 will be explained.

As shown in FIG. 1, the scan section 2 is formed with an imaging space B which is formed with a static magnetic field and in which an imaging area containing a target for imaging at the subject SU is accommodated or held. The scan section 2 applies RF pulses to the imaging area of the subject SU accommodated in the imaging space B formed with the static magnetic field, based on a control signal outputted from the operation console section 3 to acquire magnetic resonance signals produced from the imaging area, thereby executing a scan for the imaging area of the subject SU.

In the present embodiment, the scan section 2 executes the mask scan and the imaging scan so as to correspond to the TRICKS method. That is, the scan section 2 executes the mask scan thereby to acquire the magnetic resonance signals produced in the imaging area in which the fluid such as the blood flows at the subject SU, as the mask data in the state in which no contrast agent is injected into the fluid. The scan section 2 executes the imaging scan after the contrast agent has been injected into the fluid flowing through the subject, thereby acquiring the magnetic resonance signals produced in the imaging area in which the fluid containing the contrast agent flows, as the imaging data. For example, the scan section 2 executes the mask scan before the execution of the imaging scan.

Although the details of the scan section 2 will be described later, the scan section 2 executes a scan for transmitting each spatial saturation pulse to an area at least containing a fluid flowing into an imaging area upon execution of the mask scan and thereafter sequentially acquiring magnetic resonance signals as mask data every time of repetition. That is, the scan section 2 transmits the spatial saturation pulse to the area in which the fluid flowing into the imaging area exists. Here, this scan is repeatedly executed so as to correspond to respective segments divided into plural form in a k space. For example, this scan is effected on the respective segments divided into plural form so as to be symmetric via an axis passing through the center in the k space. Here, the scan section 2 executes the mask scan between the plurality of segments in such a manner that the directions of sequentially acquiring magnetic resonance signals about those segments as mask data every time of repetition TR are faced in the directions opposite to each other via the center of the k space. Described specifically, the scan section 2 executes the mask scan in such a manner that the above acquisition directions are faced toward the periphery as viewed from the center of the k space.

Respective constituent elements of the scan section 2 will be described sequentially.

The static magnetic field magnet unit 12 is of, for example, a horizontal magnetic field type. A superconductive magnet (not shown) forms a static magnetic field along the direction (z direction) of a body axis of the subject SU placed in an imaging space B in which the subject SU is accommodated or held. Incidentally, the static magnetic field magnet unit 12 may be a vertical magnetic field type other than the horizontal magnetic field type, which forms a static magnetic field along the direction in which a pair of permanent magnets faces each other.

The gradient coil unit 13 forms a gradient magnetic field by transmitting each gradient pulse to the imaging space B formed with the static magnetic field and applies or adds spatial position information to each magnetic resonance signal received by the RF coil unit 14. Here, the gradient coil unit 13 comprises three systems set so as to form a gradient magnetic field in association with three-axis directions of a z direction extending along a static magnetic field direction, an x direction and a y direction orthogonal to one another. These transmit gradient pulses in a frequency encode direction, a phase encode direction and a slice selection direction, based on a control signal outputted from the controller 30 thereby to form gradient magnetic fields. Described specifically, the gradient coil unit 13 applies the gradient magnetic field in the slice selection direction of the subject SU and selects each slice of the subject SU excited by transmission of an RF pulse by the RF coil unit 14. The gradient coil unit 13 applies the gradient magnetic field in the phase encode direction of the subject SU and phase-encodes a magnetic resonance signal from the slice excited by the RF pulse. And the gradient coil unit 13 applies the gradient magnetic field in the frequency encode direction of the subject SU and frequency-encodes the magnetic resonance signal from the slice excited by the RF pulse.

As shown in FIG. 1, the RF coil unit 14 is disposed so as to surround the subject SU. The RF coil unit 14 transmits an RF pulse corresponding to an electromagnetic wave to the subject SU within the imaging space B formed with the static magnetic field by the static magnetic field magnet unit 12, based on a control signal outputted from the controller 30 thereby to form a high frequency magnetic field. Thus, magnetization vectors based on the spins of proton in the imaging area of the subject SU are flipped. Further, the RF coil unit 14 receives an electromagnetic wave generated when each magnetization vector flipped in the imaging area of the subject SU is returned to the original magnetization vector, as a magnetic resonance signal.

The cradle 15 is a table including a horizontal plane, which places the subject SU thereon. The cradle 15 is moved between the inside and outside of the imaging space B, based on a control signal supplied from the controller 30.

The RF driver 22 drives the RF coil unit 14 to transmit an RF pulse to within the imaging space B, thereby forming a high frequency magnetic field in the imaging space B. The RF driver 22 modulates a signal sent from an RF oscillator to a signal having predetermined timing and predetermined envelope using a gate modulator on the basis of the control signal outputted from the controller 30. Thereafter, the RF driver 22 allows an RF power amplifier to amplify the signal modulated by the gate modulator and outputs the same to the RF coil unit 14, and allows the RF coil unit 14 to transmit the corresponding RF pulse.

The gradient driver 23 allows the gradient coil unit 13 to apply a gradient pulse, based on the control signal outputted from the controller 30 thereby to generate a gradient magnetic field within the imaging space B formed with the static magnetic field. The gradient driver 23 has a three-system drive circuit (not shown) in association with the three-system gradient coil unit 13.

The data acquisition unit 24 acquires each magnetic resonance signal received by the RF coil unit 14 based on the control signal outputted from the controller 30. Here, the data acquisition unit 24 phase-detects the magnetic resonance signal received by the RF coil unit 14, using a phase detector with the output of the RF oscillator of the RF driver 22 as a reference signal. Thereafter, the data acquisition unit 24 converts the magnetic resonance signal corresponding to the analog signal into a digital signal by using an A/D converter and outputs it therefrom.

The operation console section 3 will be explained.

The operation console section 3 controls the scan section 2 such that the scan section 2 executes a scan for the subject, and generates each image about the subject, based on the magnetic resonance signal obtained by the scan executed by the scan section 2 and displays the generated image.

Respective parts that constitute the operation console section 3 will be described sequentially.

The controller 30 has a computer and a memory that stores programs that allow the computer to execute predetermined data processing, and controls respective parts. Here, the controller 30 inputs operation data sent from the operation unit 32 and controls the scan section 2 based on the operation data inputted from the operation unit 32. That is, as shown in FIG. 1, the controller 30 outputs control signals to the RF driver 22, gradient driver 23 and data acquisition unit 24 and thereby controls the operations of the respective parts so as to correspond to set scan conditions. Along with it, the controller 30 outputs control signals to the data processor 31, display unit 33 and storage unit 34 to perform control thereof.

The image reconstruction unit 31 has a computer and a memory that stores therein programs for executing predetermined data processing using the computer. The image reconstruction unit 31 executes image reconstruction processing, based on the control signal supplied from the controller 30 to reconstruct each image. Here, the magnetic resonance signals acquired so a to correspond to the k space by executing the scan for the imaging area of the subject by the scan section 2 are subjected to a Fourier transformation process, thereby executing the image reconstructing process, whereby each image about the imaging area is reconstructed. And the image reconstruction unit 31 outputs data about each reconstructed image to the display unit 33.

In the present embodiment, the image reconstruction unit 31 executes the mask scan and the imaging scan such that they correspond to the TRICKS method and sequentially generate the images about the imaging area along the time base, based on the magnetic resonance signals acquired as mask data and imaging data.

The operation unit 32 is constituted of an operation device such as a keyboard, a pointing device or the like. The operation unit 32 inputs operation data from an operator and outputs the same to the controller 30.

The display unit 33 is constituted of a display device such as a CRT and displays each image on its display screen, based on the control signal outputted from the controller 30. For example, the display unit 33 displays images about input items corresponding to the operation data inputted to the operation unit 32 by the operator on the display screen in plural form. Further, the display unit 33 receives data about each image for the imaging area reconstructed by the image reconstruction unit 31 and displays the image on the display screen.

The storage unit 34 comprises a storage device such as a memory and stores various data therein. In the storage unit 34, the stored data are accessed by the controller 30 as needed.

Operation. The operation of imaging the subject SU will be explained below using the magnetic resonance imaging apparatus 1 illustrative of the present embodiment referred to above.

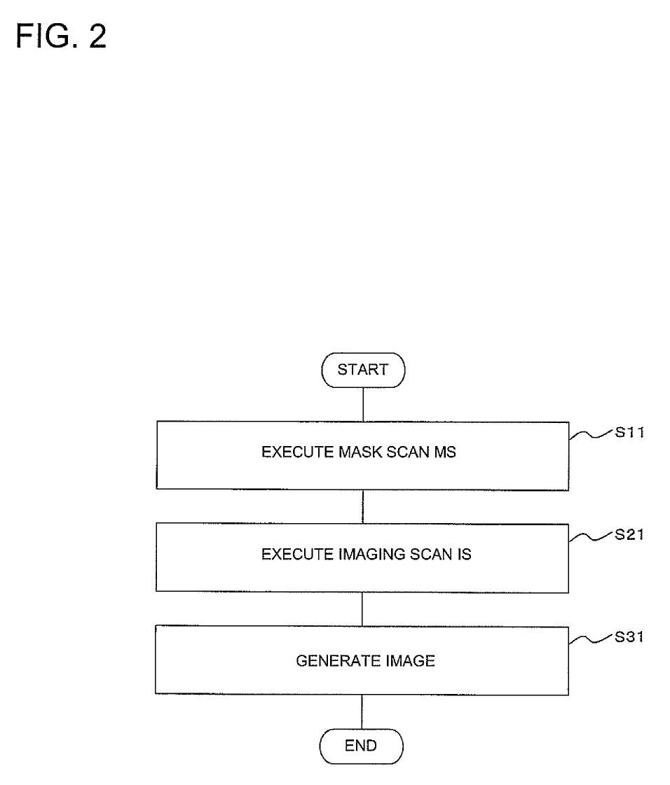

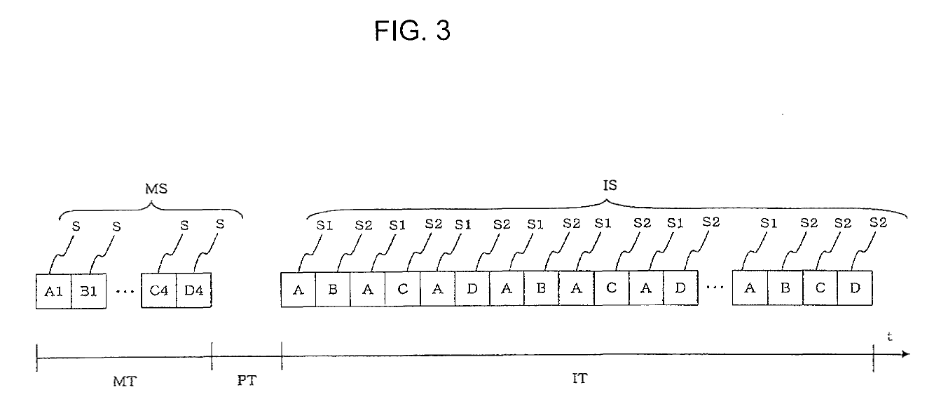

FIG. 2 is a flowchart showing operation of the first embodiment according to the invention at the time that the subject SU is imaged or photographed. FIG. 3 is a diagram showing the manner in which an imaging area of a subject is scanned by the TRICKS method in the first embodiment according to the invention. In FIG. 3, a time base is expressed in the form of the horizontal axis.

As shown in FIG. 2, a mask scan MS is first executed (S11).

Here, the scan section 2 executes the mask scan MS in such a way as to acquire, as mask data, magnetic resonance signals produced in an imaging area in which a fluid such as the blood flows at or through the subject SU, with respect to respective matrices in a k space in a state in which no contrast agent is injected into the fluid.

Described specifically, as shown in FIG. 3, scans S for respectively sequentially acquiring magnetic resonance signals as mask data every time of repetition TR are sequentially executed during a mask scan execution period MT every segment areas A1, . . . , A4, B1, . . . , B4, C1, . . . , C4, and D1, . . . , D4 partitioned so as to contain a plurality of matrices in a k space. As shown in FIG. 3, for example, the scans are repeatedly executed so as to correspond to the respective segments of k space divided into 16 segment areas A1, . . . , A4, B1, . . . , B4, C1, . . . , C4, and D1, . . . , D4.

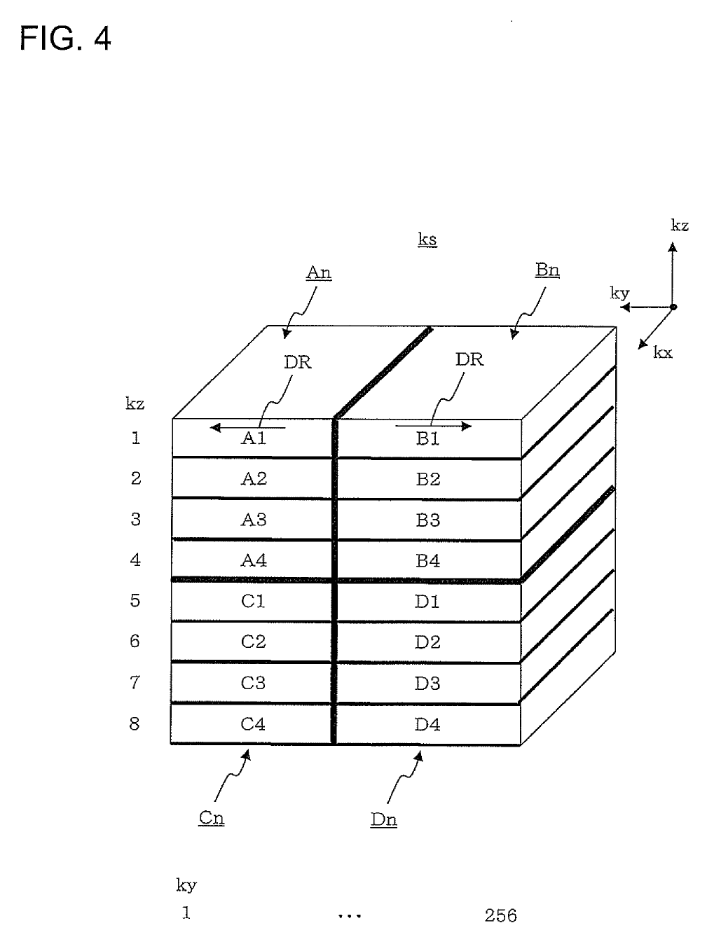

FIG. 4 is a diagram showing a k space in which magnetic resonance signals are acquired by execution of a mask scan MS in the first embodiment according to the invention.

In the present embodiment as shown in FIG. 4, a k space ks is divided so as to come to a plurality of segment areas A1, . . . , A4, B1, . . . , B4, C1, . . . , C4, and D1, . . . , D4. Here, the k space ks is divided into the plurality of segment areas A1, . . . , A4, B1, . . . , B4, C1, . . . , C4, and D1, . . . , D4 so as to be symmetric through or with respect to the center of the k space ks. The number of divisions into the segment areas is set based on a command inputted by an operator. Here, the command is inputted by the operator in consideration of saturation effects of spatial saturation pulses and an influence on imaging time to be described later. The command may automatically be set such that the spatial saturation pulses are applied at intervals defined in advance. In a three-dimensional k space ks defined by three axes of a kx axis, a ky axis and a kz axis, for example, the k space is divided into two as viewed in a ky-axis direction and divided into eight as viewed in a kz-axis direction as shown in FIG. 4. Consequently, the k space is divided into sixteen segment areas A1, . . . , A4, B1, . . . , B4, C1, . . . , C4, and D1, . . . , D4 in total. That is, the k space ks is divided into the first through sixteenth segment areas A1, . . . , A4, B1, . . . , B4, C1, . . . , C4, and D1, . . . D4 depending on a kx-ky plane and a kx-kz plane so as to be symmetric through the center of the k space ks as viewed in the ky-axis direction and symmetric through the center of the k space ks as viewed in the kz-axis direction. Described specifically, as shown in FIG. 4, four areas An, Bn, Cn and Dn divided into two equal parts in the ky-axis direction and kz-axis direction are respectively divided into four equal parts in the kz-axis direction, whereby the k space ks is divided into the sixteen segment areas A1, . . . , A4, B1, . . . , B4, C1, . . . , C4, and D1, . . . , D4. Thus, in the present embodiment, the segments are divided in such a manner that distributions of respective points in the segments are equal to one another even at any segment from the center of the k space to its peripheral portion.

As shown in FIG. 3, the scans S are sequentially executed in segment area units so as to correspond to the respective segments. The scans S are sequentially executed with respect to the respective segments as in the case of, for example, A1, B1, A2, B2, A3, B3, A4, B4, C1, D1, C2, D2, C3, D3, C4 and D4.

Here, as shown in FIG. 4, the scans are executed in such a manner that the directions DR of sequentially acquiring the magnetic resonance signals as mask data every time of repetition TR so as to correspond to the respective matrices at the segment areas A1, . . . , A4, B1, . . . , B4, C1, . . . , C4, and D1, . . . , D4 are faced in the directions opposite to each other between the segment areas symmetric through the center of the k space ks. As shown in FIG. 4 by way of example, the scan are executed in such a manner that the acquisition directions DR are faced toward the periphery along the ky-axis direction as viewed from the center of the k space ks. That is, as shown in FIG. 4, the scans are effected on the segment areas B1, B2, B3, B4, D1, D2, D3 and D4 adjacent to the segment areas A1, A2, A3, A4, C1, C2, C3 and C4 via the kx-kz plane in such a manner that the acquisition direction DR is faced in the opposite direction.

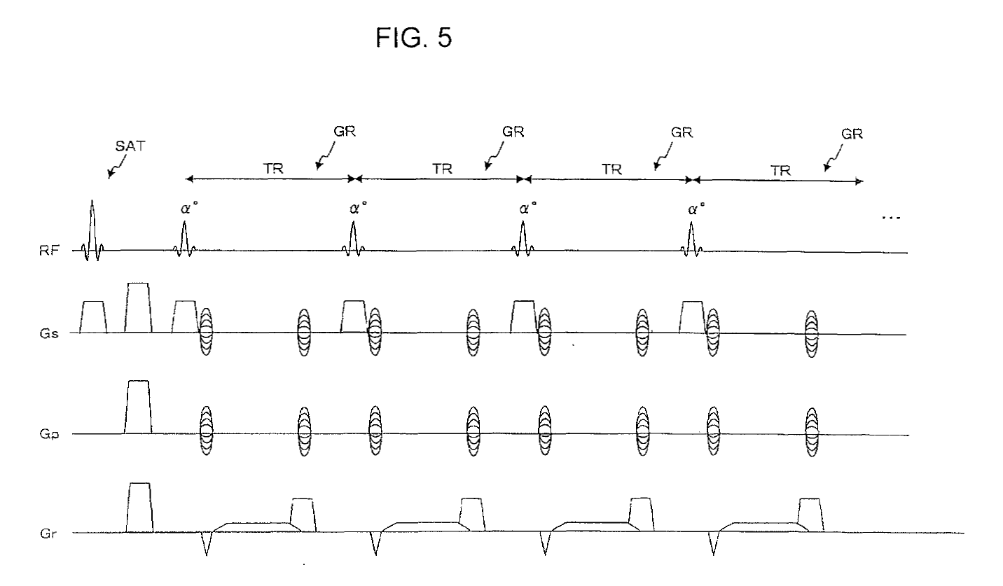

FIG. 5 is a pulse sequence diagram at the time that mask data are acquired with respect to respective segments upon execution of a mask scan MS in the first embodiment according to the invention. FIG. 5 shows an RF pulse RF, a gradient pulse Gs in a slice selection direction, a gradient pulse Gp in a phase encode direction orthogonal to the slice selection direction, and a gradient pulse Gr in a frequency encode direction orthogonal to the slice selection direction and the phase encode direction. Incidentally, the vertical axis indicates strength and the horizontal axis indicates time in the present embodiment.

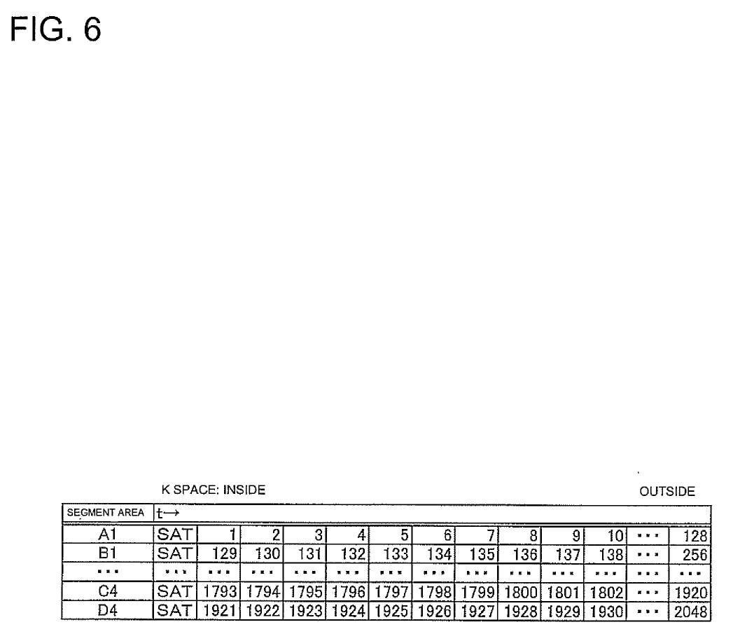

FIG. 6 is a diagram showing a sequence at the time that mask data are acquired with respect to matrices constituting segments upon execution of the mask scan MS in the first embodiment according to the invention.

In the present embodiment, as shown in FIG. 5, a spatial saturation pulse SAT is first transmitted to each area containing a fluid that flows into the corresponding imaging area. For example, a 100° pulse and a spoiler pulse for allowing horizontal magnetization to disappear are used as spatial saturation pulses. Thereafter, magnetic resonance signals are sequentially acquired every time of repletion TR as mask data at a pulse sequence GR corresponding to the first gradient echo method, for example. Described specifically, α° pulses are transmitted together with a slice selection gradient pulse in such a manner that magnetization moments of spins in the imaging areas are flipped at flip angles of α°, thereby exciting the imaging areas selectively. Next, a gradient pulse for phase encoding is transmitted in each of the slice selection and phase-encode directions. That is, in order to effect imaging or photographing on a three-dimensional imaging area, a gradient pulse for performing phase encoding in the slice selection direction is also transmitted in such a manner that mask data are acquired corresponding to a three-dimensional k space. Next, a gradient pulse is transmitted in the frequency encode direction to sample the magnetic resonance signals. Thereafter, a spoiler pulse for allowing horizontal magnetization to disappear is transmitted in the frequency encode direction, and a gradient pulse for rewinding is transmitted in each of the slice selection direction and the phase encode direction. Here, the sampling of the magnetic resonance signals is executed while the phase encoding is being changed stepwise every time of repetition TR. Thus, the plurality of mask data are acquired after the transmission of one spatial saturation pulse SAT.

As shown in FIG. 6 by way of example, 128 mask data are sequentially acquired every time of repletion TR from the side of the center of the k space ks to its peripheral side at the segment area A1. Likewise, 128 mask data are sequentially acquired from the side of the center of the k space ks to its peripheral side even at other segment areas.

Next, an imaging scan IS is executed as shown in FIG. 2 (S21).

Here, as shown in FIG. 3, a contrast agent is injected into the fluid flowing through the subject SU during a temporary stop period PT subsequent to the elapse of the mask scan execution period MT. Thereafter, the scan section 2 executes the imaging scan IS during an imaging scan execution period IT so as to collect or acquire magnetic resonance signals produced in an imaging area in which the fluid containing the contrast agent flows, as imaging data.

Described specifically, as shown in FIG. 3, magnetic resonance signals are sequentially acquired every time of repletion TR as imaging data so as to correspond to the respective segments of the k space divided into four of first, second, third and fourth segment areas A, B, C and D, for example.

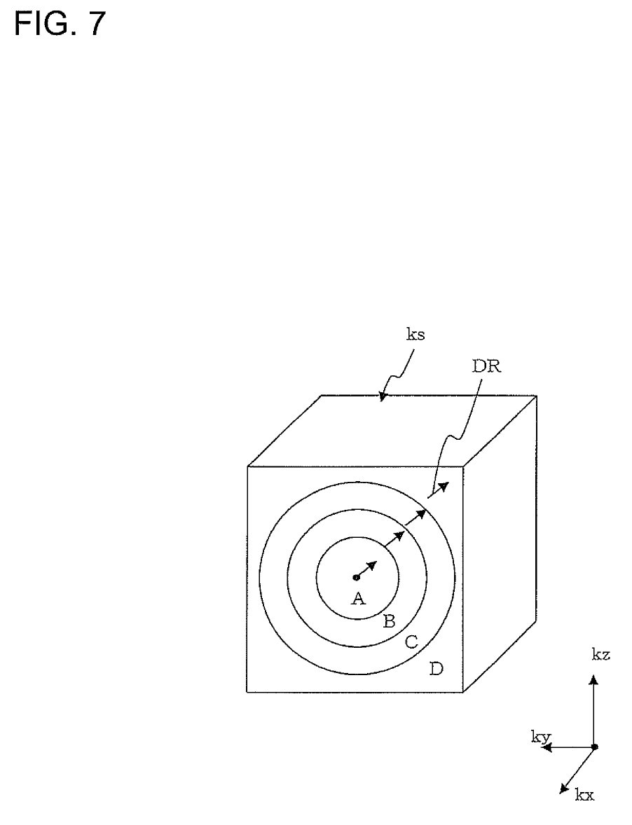

FIG. 7 is a diagram illustrating a k space in which magnetic resonance signals are acquired upon execution of an imaging scan IS in the first embodiment according to the invention.

In the present embodiment as shown in FIG. 7, the k space ks is divided into a plurality of segments A, B, C and D from a low-frequency region located in its center to a high-frequency region located at its periphery. For example, the first segment area A is partitioned in the k space ks so as to correspond to a central region including the center along a kx-axis direction. The second segment area B, third segment area C and fourth segment area D are partitioned stepwise so as to extend from the first segment area A to the periphery of the k space. Here, as shown in FIG. 7, the first segment area A is partitioned so as to reach a cylindrical form with the kx-axis direction passing through the center of the k space ks as the axis. The second segment area B is partitioned so as to cover the periphery of the first segment area A in the form of a cylinder with the kx-axis direction passing through the center of the k space ks as the axis. Then, the third segment area C is partitioned so as to cover the periphery of the second segment area B in the form of a cylinder with the kx-axis direction passing through the center of the k space ks as the axis. Further, the fourth segment area D is partitioned so as to cover the periphery of the third segment area C in the k space ks.

Magnetic resonance signals are acquired with respect to the respective segment areas A, B, C and D.

Unlike the mask scan MS, as shown in FIG. 3 here, a first scan S1 for acquiring a magnetic resonance signal corresponding to the first segment area A located so as to include the center in the k space, and a second scan S2 for acquiring a magnetic resonance signal corresponding to each of other second, third and fourth segment areas B, C and D are repeatedly executed alternately each other. As to the second scans S2, the magnetic resonance signals corresponding to the second, third and fourth segment areas B, C and D, which are plural segment areas divided around the first segment area A in the k space, are sequentially acquired in segment area units so as to interpose the execution of the plurality of first scans S1 between the second scans S2. That is, after the magnetic resonance signals each corresponding to the second segment area B have been acquired upon execution of the second scans S2, magnetic resonance signals each corresponding to the third segment area C, which is a segment area different from the second segment area B, are acquired via the execution of the first scans S1. After the magnetic resonance signals each corresponding to the third segment area C have been acquired upon execution of the second scans S2, magnetic resonance signals each corresponding to the fourth segment area D, which is a segment area different from the second segment area and the third segment area B, are acquired via the execution of the first scans S1.

Described specifically, upon execution of the imaging scan IS as shown in FIG. 3, the magnetic resonance signals corresponding to the segments are acquired in such a sequence as in the case of the first segment area A, second segment area B, first segment area A, third segment area C, first segment area A, fourth segment area D, first segment area A, . . . . Thus, upon the execution of the imaging scan IS, the magnetic resonance signals corresponding to the first segment areas A located so as to contain the center of the k space ks are acquired greater than the magnetic resonance signals corresponding to other second, third and fourth segment areas B, C and D located around the k space ks.

Upon completion of the imaging scan IS, however, as shown in FIG. 3, the scans are executed in the order of the second segment area B, the third segment area C and the fourth segment area D from the first segment area A to the periphery in a manner similar to the related art without alternately repeating the first scan S1 and the second scan S2.

As shown in FIG. 7 here, the scan is executed in such a manner that the direction DR of sequentially acquiring the magnetic resonance signals as imaging data every time of repetition TR in the first, second, third and fourth segment areas A, B, C and D is faced from the center of the k space to its periphery.

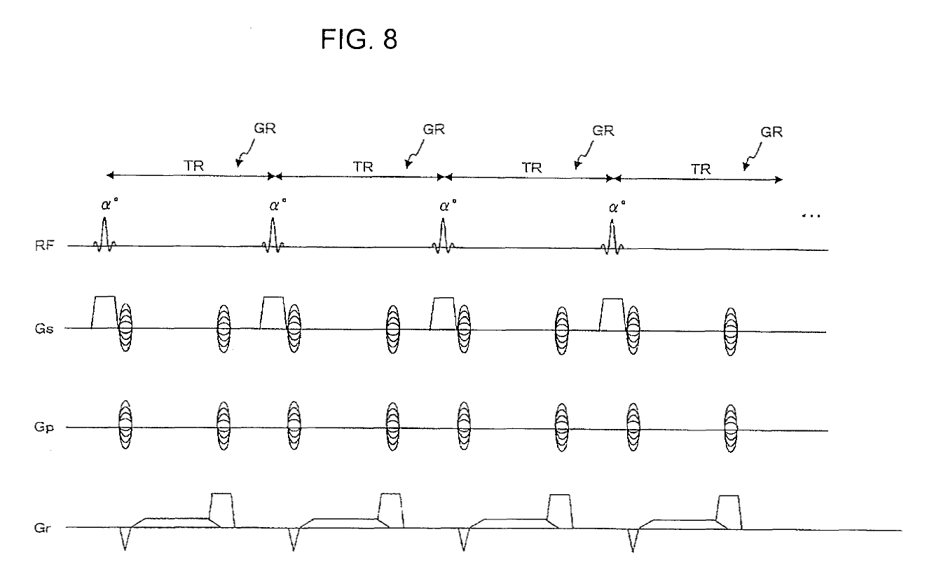

FIG. 8 is a pulse sequence at the time that imaging data are acquired every segment area upon execution of the imaging scan IS in the first embodiment according to the invention. FIG. 8 shows an RF pulse RF, a gradient pulse Gs in a slice selection direction, a gradient pulse Gp in a phase encode direction orthogonal to the slice selection direction, and a gradient pulse Gr in a frequency encode direction orthogonal to the slice selection direction and the phase encode direction. Incidentally, the vertical axis indicates strength and the horizontal axis indicates time in the present embodiment.

The spatial saturation pulse SAT is not transmitted to the area containing the fluid flowing through each imaging area unlike the case (refer to FIG. 5) of the mask scan MS in the present embodiment as shown in FIG. 8. However, magnetic resonance signals are sequentially acquired every time of repletion TR as imaging data in accordance with the pulse sequence corresponding to the first gradient echo method in a manner similar to the mask scan MS. Here, the time of repetition TR at the imaging scan IS is set so as to be equal to the time of repletion TR at the mask scan MS, and the corresponding scan is executed.

Next, the generation of each image is done as shown in FIG. 2 (S31).

Here, the mask scan MS and the imaging scan IS are executed so as to correspond to the TRICKS method as mentioned above. Based on magnetic resonance signals acquired as mask data and imaging data, the image reconstruction unit 31 sequentially generate images about an imaging area therefor along the time base.

In the present embodiment, a mask image is image-reconstructed based on the mask data and an imaging image is image-reconstructed based on the imaging data. Thereafter, each difference image is generated by subtracting data about the imaging image from data about the mask image.

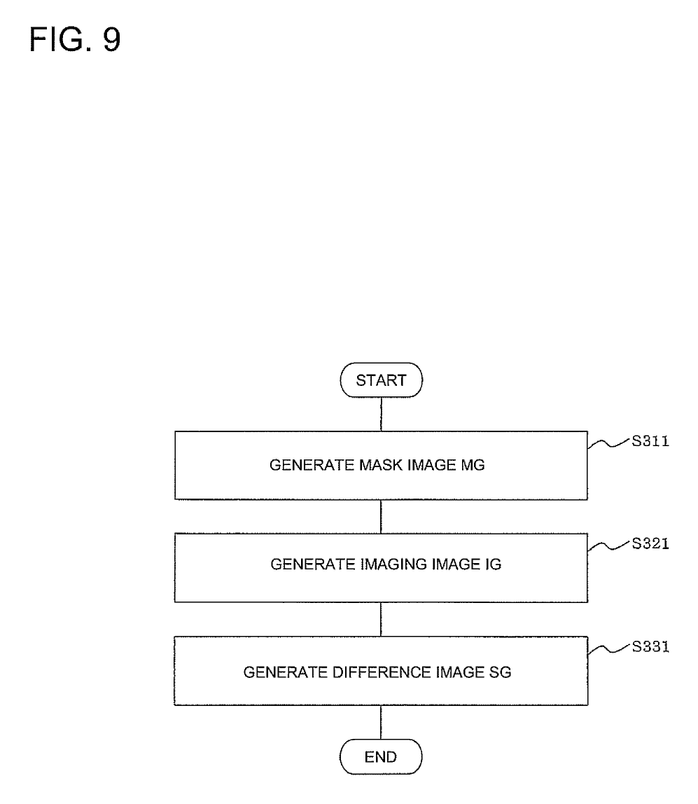

FIG. 9 is a flowchart showing the operation of sequentially generating images about an imaging area along a time base in the first embodiment according to the invention.

As shown in FIG. 9, a mask image MG is first generated (S311).

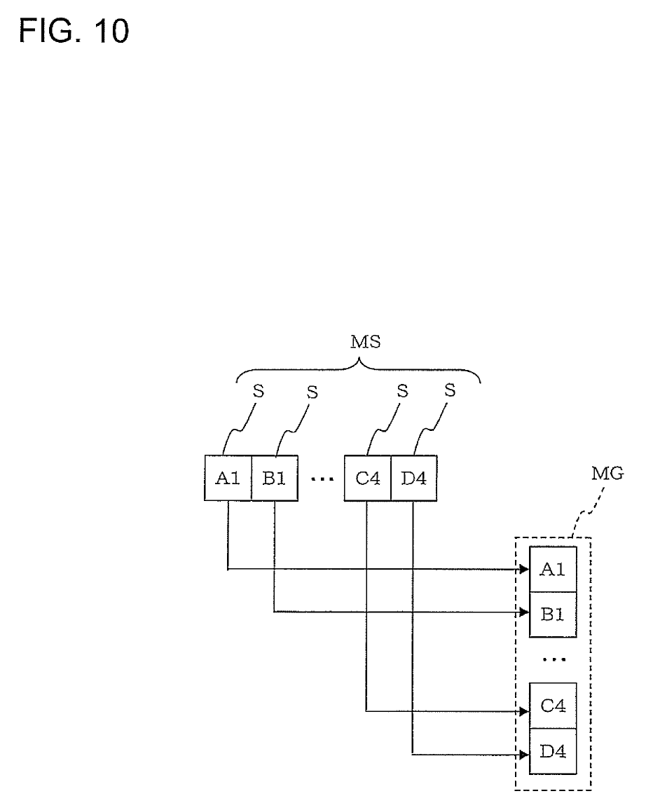

FIG. 10 is a diagram showing the manner in which a mask image MG is generated in the first embodiment according to the invention.

Here, as shown in FIG. 10, the mask image MG is image-reconstructed using mask data acquired or collected so as to correspond to sixteen segment areas upon execution of a mask scan MS.

Next, imaging images IG are generated as shown in FIG. 9 (S321).

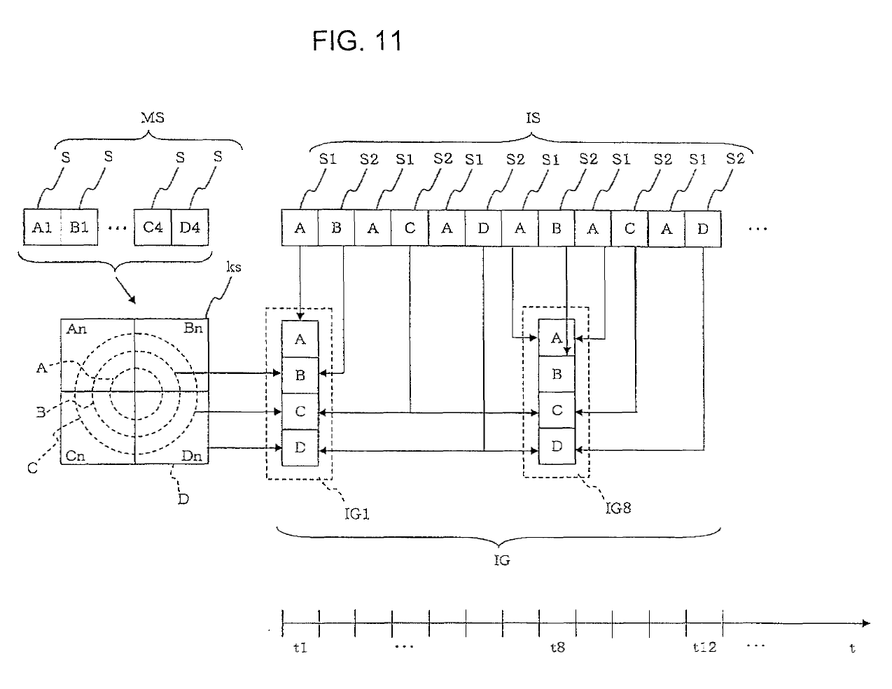

FIG. 11 is a diagram illustrating the manner in which imaging images IG are generated in the first embodiment according to the invention.

In the present embodiment, as shown in FIG. 11, the imaging images IG are sequentially image-reconstructed along a time base t. That is, the imaging images IG are sequentially image-reconstructed along the time base t so as to correspond to time phases at which first and second scans S1 and S2 are executed as an imaging scan IS.

Described specifically, when the first and second scans S1 and S2 are sequentially executed as the imaging scan IS as in the case of a first time phase t1, . . . , an eighth time phase t8, . . . , and a twelfth time phase t12 as shown in FIG. 11, a first imaging image IG1, . . . , an eighth imaging image IG8, . . . , a twelfth imaging image IG12, . . . are sequentially image-reconstructed with respect to the first time phase t1, . . . , eighth time phase t8, . . . , twelfth time phase t12, . . . .

Upon generation of the first imaging image IG1 as shown in FIG. 11, for example, a magnetic resonance signal acquired so as to correspond to a first segment area A by execution of the first scan S1 at the first time phase t1, and magnetic resonance signals acquired by scans executed so as to correspond to second, third and fourth segment areas B, C and D other than the first segment area A before and after the execution of the first scan S1 are respectively used. That is, magnetic resonance signals corresponding to segments other than a segment, acquired by each scan executed at a predetermined time phase are interpolated by a magnetic resonance signal acquired by a scan executed at another time phase. When, at this time, the scans S corresponding to the other first and second scans S1 and S2 in the imaging scan IS are not executed and the scans S in the mask scan MS are executed before the execution of the first scan S1 at the first time phase t1 as shown in FIG. 11, mask data about portions respectively corresponding to the second, third and fourth segment areas B, C and D in the k space ks in which the imaging data are acquired as shown in FIG. 7, are used in a k space ks in which mask data are acquired as indicated by dotted lines in FIG. 11.

That is, as shown in FIG. 11, the magnetic resonance signal acquired as the imaging data at the first time phase t1 is used in the first segment area A. The magnetic resonance signal acquired as the mask data so as to correspond to the second segment area B in the mask scan MS, and the magnetic resonance signal acquired as the imaging data at the second time phase t2 in the imaging scan IS are used in the second segment area B. Here, the average value of both is used, for example. Likewise, the magnetic resonance signal acquired as the mask data so as to correspond to the third segment area C at the mask scan MS, and the magnetic resonance signal acquired as the imaging data at the fourth time phase t4 at the imaging scan IS are used in the third segment area C. Further, likewise, the magnetic resonance signal acquired as the mask data so as to correspond to the fourth segment area D at the mask scan MS, and the magnetic resonance signal acquired as the imaging data at th sixth time phase t6 at the imaging scan IS are used in the fourth segment area D.

Upon execution of the eighth imaging image IG8 as shown in FIG. 11, for example, the magnetic resonance signal acquired so as to correspond to the second segment area B by execution of the second scan S2 at the eighth time phase t8, and the magnetic resonance signals acquired by the scans executed so as to correspond to the first, third and fourth segment areas A, C and D other than the second segment area B before and after the second scan S2 are respectively used.

That is, as shown in FIG. 11, the magnetic resonance signal acquired as the imaging data at the eighth time phase t8 is used in the second segment area B. In a manner similar to the above, the magnetic resonance signal acquired as the imaging data at the seventh time phase t7, and the magnetic resonance signal acquired as the imaging data at the ninth time phase t9 are respectively used in the first segment area A. The magnetic resonance signal acquired as the imaging data at the fourth time phase t4, and the magnetic resonance signal acquired as the imaging data at the tenth time phase t10 are respectively used in the third segment area C. The magnetic resonance signal acquired as the imaging data at the sixth time phase t6, and the magnetic resonance signal acquired as the imaging data at the twelfth time phase t12 are respectively used in the fourth segment area D.

Next, a difference image SG is generated as shown in FIG. 9 (S331).

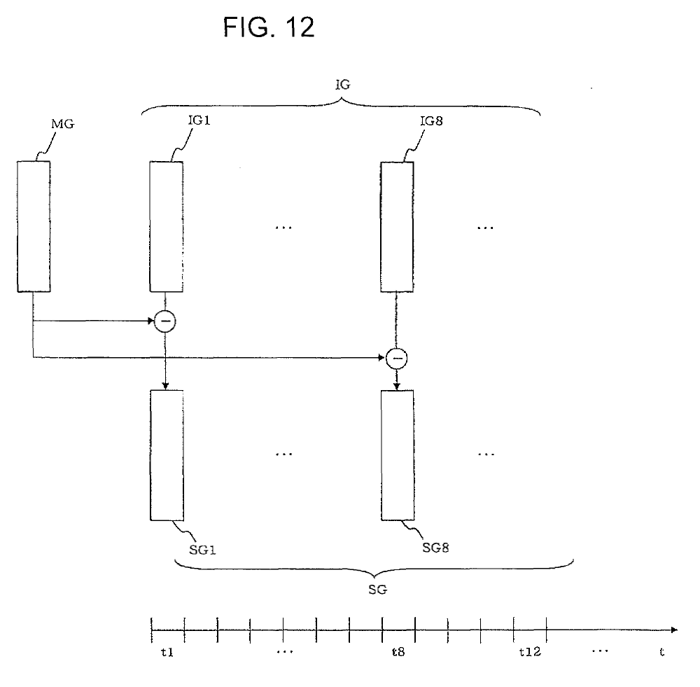

FIG. 12 is a diagram showing the manner in which each difference image SG is generated in the first embodiment according to the invention.

Here, as shown in FIG. 12, image data about each mask image MG is subtracted from each of image data about imaging images IG generated along a time base t to generate a difference image SG as described above.

For example, the image data about the mask image MG is subtracted from image data about a first imaging image IG1 generated so as to correspond to the first time phase t1 to generate a first difference image SG1. Likewise, a second difference image SG2, . . . , an eighth difference image SG8, . . . are sequentially generated so as to correspond to the respective time phases t2, . . . , t8, . . . .

Since, as described above, the difference image SG is obtained by subtracting the mask image MG about the imaging area free of the inflow of the contrast agent from the imaging image IG about the imaging area in which the contrast agent flows, each portion in which the contrast agent flows is generated as an image high in contrast.

Upon executing the mask scan MS in the present embodiment as described above, the scans for transmitting the spatial saturation pulse SAT to each area containing the fluid that flows into the corresponding imaging area and thereafter sequentially acquiring the magnetic resonance signals as the mask data every time of repletion TR are sequentially repeatedly carried out by the first gradient echo method so as to correspond to the segment areas A1, . . . , A4, B1, . . . , B4, C1, . . . , C4, and D1, . . . , D4 divided into plural form in the k space. Therefore, the transmission of the spatial saturation pulse makes it possible to suppress that each magnetic resonance signal acquired as mask data from each vascular portion through which the fluid such as the blood flows is brought to a high signal due to the influence of an inflow effect upon acquisition of the mask data. Thus, when the image data about the mask image MG generated based on the mask data is subtracted from the image data about the imaging image IG, a portion in which the contrast agent flows in each difference image SG, is generated with high contract. Since the vascular portion which has heretofore been brought to the high signal at the mask image due to the inflow effect can be confirmed at the difference image SG, it becomes easy to recognize the position of the blood vessel regardless of the presence or absence of the contrast agent. When the spatial saturation pulse SAT is transmitted every time of repetition TR, the whole scan time increases in consequence. Since, however, the mask data are acquired during plural repetition times TR after the transmission of the spatial saturation pulse SAT in the present embodiment, it is possible to suppress an increase in scan time.

Further, in the present embodiment, the segments are divided so as to differ from one another in the k space in which the imaging data are acquired at the imaging scan IS, and the k space in which the mask data are acquired at the mask scan MS. The k space in which the mask data are acquired at the mask scan MS, are divided into the plural segments such that they become symmetric through the center thereof.

Therefore, since the application of the spatial saturation pulse SAT at the mask scan MS can be carried out regardless of the data acquisition method at the imaging scan IS, the method of applying the spatial saturation pulse at the mask scan MS can freely be set.

Upon execution of the mask scan MS in the present embodiment, the mask scan MS is executed in such a manner that the directions DR of sequentially acquiring the magnetic resonance signals with respect to the respect segments as the mask data every time of repetition are faced in the directions opposite to each other through the center of the k space.

Therefore, the influence of the spatial saturation pulse SAT becomes gentle in the whole k space. Described specifically, a subsequently-obtained signal strength changes with the influence of the application of the spatial saturation pulse SAT. This change increases immediately after the application of the spatial saturation pulse SAT and thereafter converges to a stable signal strength. Since the data are acquired from the center of the k space to its peripheral portion after application of the spatial saturation pulses SAT at all segments, a change in signal due to the spatial saturation pulse SAT becomes large in the center of the k space and small outside at any segment. Since the segments are laid out so as to be symmetric through the center of the k space, the magnitude of the change in signal in the entire k space gently changes from the center of the k space to the outside. Therefore, the signal gently changes over all as compared with the case in which the spatial saturation pulse is applied without examining the segments and the change in signal with its application is dispersed over the entire k space, thereby producing the effect that deterioration in image quality with its signal change can be suppressed to the minimum.

In the present embodiment as well, the saturation effect of each spatial saturation pulse SAT can be enhanced. Described specifically, the saturation effect of the spatial saturation pulse SAT is heightened immediately after its application and thereafter becomes weak. Since the data are acquired from the center of the k space to its peripheral portion after the application of the spatial saturation pulses SAT at all segments, the saturation effect of the spatial saturation pulse SAT becomes strong in the center of the k space and weak outside at any segment. Since the segments are laid out so as to be symmetric through the center of the k space, the effects that the saturation effect of the spatial saturation pulse SAT becomes strong evenly in the center of the k space in which contrast is determined, and the effect of the spatial saturation pulse SAT at the mask image MG can be enhanced, are produced as compared with the case in which the data acquired immediately after the application of the spatial saturation pulse SAT are dispersed over the entire k space.

Thus, the present embodiment is capable of enhancing image quality and making it easy to carry out an image diagnosis efficiently.

Second embodiment. A second embodiment according to the invention will be explained below.

The present embodiment is different from the first embodiment in terms of a segment dividing method at the acquisition of magnetic resonance signals in a k space ks. Except for this point, the present embodiment is similar to the first embodiment. Therefore, the description of dual parts will be omitted.

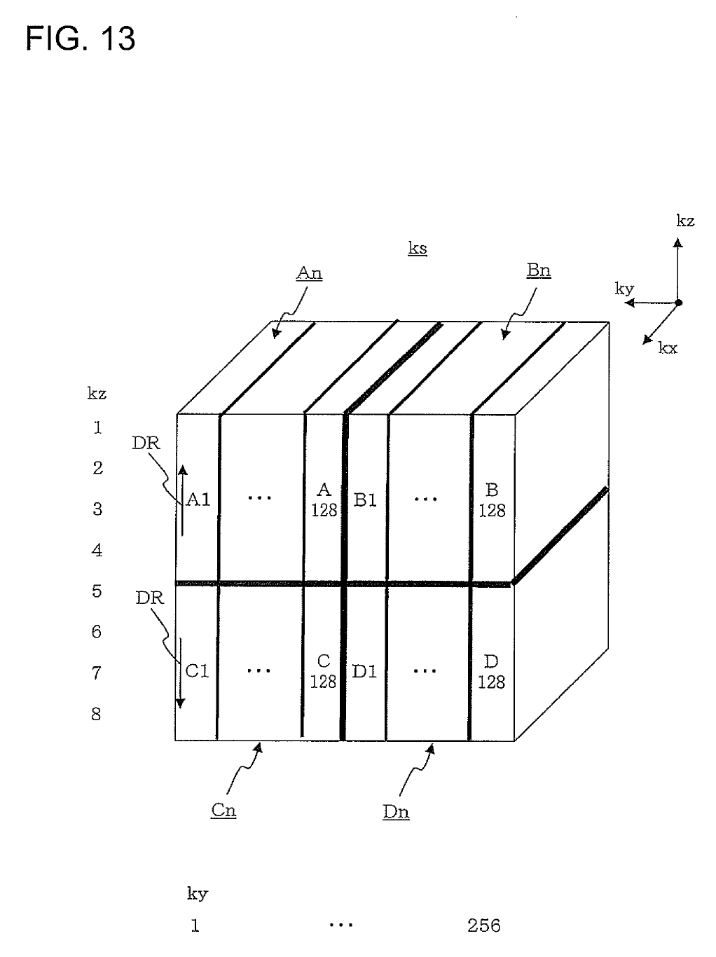

FIG. 13 is a diagram showing a k space in which magnetic resonance signals are acquired by execution of a mask scan MS in the second embodiment according to the invention.

In the present embodiment, as shown in FIG. 13, a three-dimensional k space ks defined by three axes of a ks axis, a ky axis and a kz axis is divided into two as viewed in a kz-axis direction and divided into 256 as viewed in a ky direction. Thus, the k space ks is divided into 512 segment areas A1, . . . , A128, B1, . . . , B128, C1, . . . , C128, and D1, . . . , D128. That is, as shown in FIG. 13, four areas An, Bn, Cn and Dn divided into two equal parts in the ky-axis direction and kz-axis direction respectively are respectively divided into 128 equal parts in the ky-axis direction, whereby the k space ks is divided into the 512 segment areas A1, . . . , A128, B1, . . . , B128, C1, . . . , C128 and D1, . . . , D128. The mask scan is carried out in such a manner that the directions DR in which the magnetic resonance signals are sequentially acquired as mask data every time or repetition TR at the segment areas A1, . . . , A128, B1, . . . , B128, C1, . . . , C128, and D1, . . . , D128 are faced in the directions opposite to each other through the center of the k space ks. As shown in FIG. 13 here, the mask scan is executed in such a manner that the acquisition directions DR are faced toward the periphery of the k space along the kz direction as viewed from the center of the k space ks. That is, as shown in FIG. 13, the mask scan is effected on the segment areas A1, . . . , A128 and B1, . . . , B128 and the segment areas C1, . . . , C128 and D1, . . . , D128 adjacent thereto one another via a kx-ky plane in such a manner that the acquisition directions DR are faced in the directions opposite to each other. For example, scans S are sequentially carried out with respect to respective segments as in the order of A1, C1, A2, C2, . . . , B127, D127, B128 and D128.

Using mask data acquired by executing the mask scan MS in this way, difference images SG are generated in a manner similar to the first embodiment.

Since the mask scan MS is carried out in a manner similar to the first embodiment in the present embodiment as described above, image quality can be enhanced and efficient execution of an image diagnosis can be facilitated.

Third embodiment. A third embodiment according to the invention will be explained below.

The present embodiment is different from the first embodiment in terms of a segment dividing method at the time that magnetic resonance signals are acquired in a k space ks upon execution of a mask scan MS. Except for this point, the present embodiment is similar to the first embodiment. Therefore, the description of dual parts will be omitted.

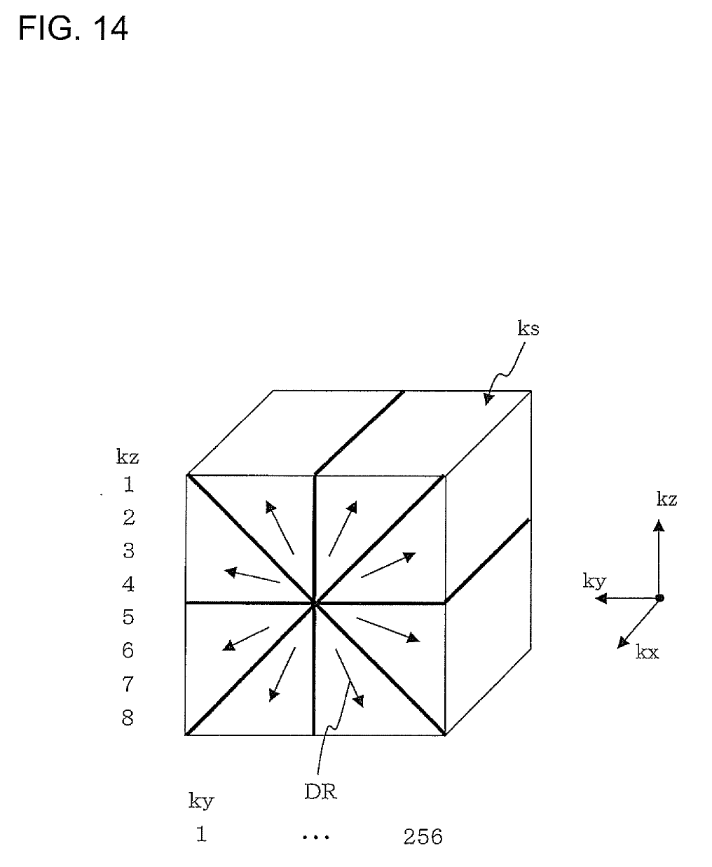

FIG. 14 is a diagram showing the k space in which the magnetic resonance signals are acquired upon execution of the mask scan MS in the third embodiment according to the invention.

In the present embodiment, as shown in FIG. 14, a three-dimensional k space ks defined by three axes of a kx axis, a ky axis and a kz axis is divided into segments symmetric through the center of a kz-ky plane defined by the ky axis and the kz axis in the three-dimensional k space ks. The mask scan MS is executed in such a manner that the directions DR of sequentially acquiring the magnetic resonance signals as mask data every time of repetition TR at the segments having divided the k space ks are faced in the directions opposite to each other through the center of the k space ks. As shown in FIG. 14 here, the mask scan MS is carried out in such a manner that the acquisition directions DR are faced to the periphery of the k space ks as viewed from the center thereof.

Using the mask data acquired by executing the mask scan MS in this way, difference images SG are generated in a manner similar to the first embodiment.

Since the mask scan MS is carried out in a manner similar to the first embodiment in the present embodiment as described above, image quality can be enhanced and efficient execution of an image diagnosis can be facilitated.

Fourth embodiment. A fourth embodiment according to the invention will be explained below.

The present embodiment is different from the first embodiment in terms of a method of acquiring magnetic resonance signals in a k space ks upon execution of a mask scan MS. Except for this point, the present embodiment is similar to the first embodiment. Therefore, the description of dual parts will be omitted.

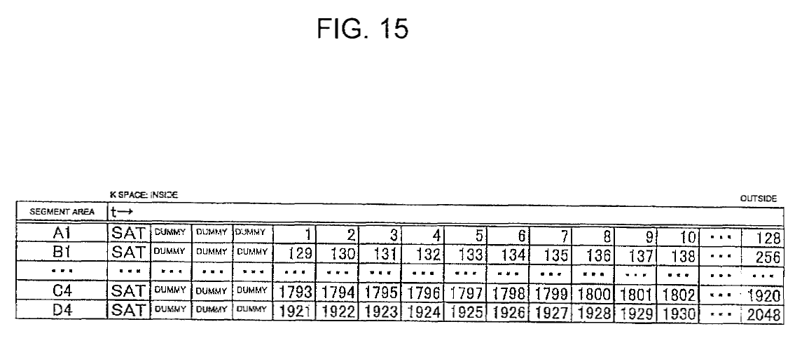

FIG. 15 is a diagram illustrating a sequence at the time that mask data are acquired with respect to matrices constituting respective segments upon execution of a mask scan MS in the fourth embodiment according to the invention.

As shown in FIG. 15, upon execution of the mask scan MS in the present embodiment, scans are executed in such a manner that magnetic resonance signals corresponding to a segment area A1 are acquired in a k space ks in a manner similar to the first embodiment. Here, a spatial saturation pulse SAT is transmitted to an area containing a fluid that flows into an imaging area. Thereafter, for example, a pulse sequence GR corresponding to the first gradient echo method is sequentially carried out every time of repetition TR. Unlike the first embodiment in the present embodiment, no mask data are acquired during a predetermined repetition time TR from after the transmission of the spatial saturation pulse SAT. That is, so-called dummy acquisition is performed a predetermined number of times. Thereafter, the magnetic resonance signals are sequentially acquired as mask data every time of repetition TR.

Thereafter, scans are similarly effected even on other segment areas A2, A3, A4, B1, B2, B3, B4, C1, C2, C3, C4, D1, D2, D3 and D4 to acquire mask data.

Using the mask data acquired by executing the mask scan MS in this way, difference images SG are generated in a manner similar to the first embodiment.

Thus, since the mask scan MS is carried out in a manner similar to the first embodiment, the present embodiment is capable of enhancing image quality and facilitating efficient execution of an image diagnosis. Further, upon execution of the mask scan MS in the present embodiment, the magnetic resonance signals are sequentially acquired as the mask data every time of repetition TR after the elapse of the repetition time TR free of acquisition of the magnetic resonance signals as the mask data after the transmission of the spatial saturation pulse SAT, unlike the first embodiment. While each signal is disturbed due to the application of the spatial saturation pulse SAT, the image quality is deteriorated when the signal is obtained in the center of the k space ks. On the other hand, since the dummy acquisition is carried out and the mask data are acquired after stabilization of each signal, the present embodiment can provide a further improvement in image quality.

Fifth embodiment. A fifth embodiment according to the invention will be explained below.

The present embodiment is different from the fourth embodiment in terms of a method for acquiring magnetic resonance signals in a k space ks upon execution of a mask scan MS. Except for this point, the present embodiment is similar to the first embodiment. Therefore, the description of dual parts will be omitted.

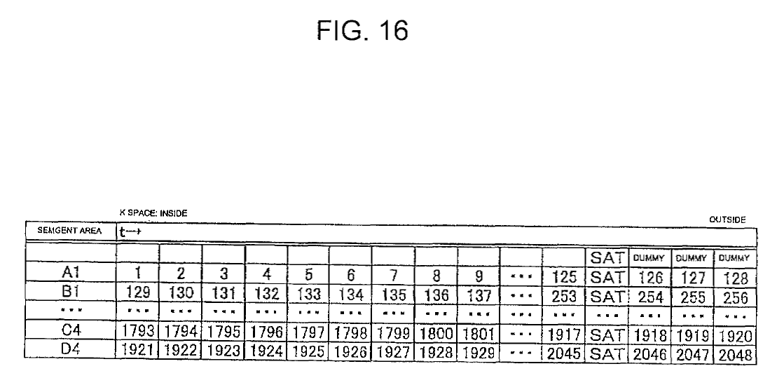

FIG. 16 is a diagram showing a sequence at the time that mask data are acquired with respect to matrices constituting segments upon execution of the mask scan MS in the fifth embodiment according to the invention.

Upon execution of the mask scan MS in the present embodiment as shown in FIG. 16, a spatial saturation pulse SAT is transmitted to an area containing a fluid that flows into an imaging area. Thereafter, for example, a pulse sequence GR corresponding to the first gradient echo method is sequentially carried out every time of repetition TR. Here, dummy acquisition that no mask data are acquired during a predetermined repetition time TR from after the transmission of the spatial saturation pulse SAT, is performed a predetermined number of times.

Thereafter, magnetic resonance signals corresponding to a segment area A1 are sequentially acquired as mask data in a k space ks every time of repetition TR. Here, magnetic resonance signals are sequentially acquired as mask data so as to correspond to a plurality of matrices arranged from a first matrix located on the center side of the k space ks to a 125th matrix located at its periphery. Thereafter, a spatial saturation pulse SAT is transmitted. Then, magnetic resonance signals are sequentially acquired as mask data so as to correspond to a plurality of matrices from a 126th matrix located on the center side of the k space ks to a 128th matrix located at its periphery.

Thereafter, scans are sequentially effected even on other segment areas A2, A3, A4, B1, B2, B3, B4, C1, C2, C3, C4, D1, D2, D3 and D4 in a manner similar to the first segment area Aa to acquire mask data.

Using the mask data acquired by executing the mask scan MS in this way, difference images SG are generated in a manner similar to the first embodiment.

Unlike the fourth embodiment, upon execution of the mask scan MS in the present embodiment as described above, spatial saturation pulses SAT are transmitted during sequential acquisition of the mask data with respect to the plurality of matrices constituting segments without transmitting the spatial saturation pulses SAT before the sequential acquisition of the mask data with respect to the plurality of matrices constituting the segments. That is, each spatial saturation pulse SAT is transmitted in the course of the segments in the present embodiment.

While each signal is disturbed due to the application of the spatial saturation pulse SAT, the image quality is deteriorated when the signal is obtained in the center of the k space ks. Although the spatial saturation pulse SAT is applied at the beginning of the segments and the dummy acquisition is executed, thereby stabilizing each signal in the center of the k space in the fourth embodiment, an imaging time also increases with an increase in dummy acquisition. As in the present embodiment, the dummy acquisition or the process of acquiring masks data corresponding to an area located on the outer side of the k space is made during a period up to the acquisition of the mask data on the center side of the k space, whereby the number of dummy acquisitions executed over its entirety is reduced in addition to the fact that acquisitions of the same number as the fourth embodiment are done from the application of the spatial saturation pulse SAT to the acquisition of the center of the k space, thereby making it possible to obtain each stable signal about the center of the k space ks and suppress prolongation of the imaging time. Incidentally, dummy pulses may be added after the spatial saturation pulses SAT applied to all segments of FIG. 16 to stabilize each signal obtained immediately after the application of each spatial saturation pulse SAT.

Incidentally, the magnetic resonance imaging apparatus 1 according to the above embodiment is equivalent to a magnetic resonance imaging apparatus of the invention. The scan section 2 of the present embodiment corresponds to a scan section of the invention.

Upon implementation of the invention, the invention is not limited to the above embodiments. Various modifications can be adopted.

Upon carrying out imaging in a two-dimensional area, the invention may be adapted.

Although the k spaces in which the magnetic resonance signals are acquired at the mask scan MS and the imaging scan IS are respectively divided into the plural segments by the different methods, the numbers of divisions thereof are arbitrary respectively.

Although a description has been made of the case in which the difference processing is done between the mask image MG and the imaging image IG after the generation of the mask image MG and the imaging image IG thereby to generate the difference image SG, the invention is not limited to it. For example, difference processing is carried out between mask data acquired by execution of a mask scan and imaging data acquired by execution of an imaging scan IS thereby to calculate difference data. Thereafter, image reconstruction processing may be effected on the difference data such that the difference image SG is generated.

Although a description has been made of the case in which each spatial saturation pulse is transmitted, the invention may be applied to a case in which another preparation pulse is transmitted in place of the spatial saturation pulse.

The spatial saturation pulses may selectively be applied to slice areas or may non-selectively be applied thereto. When the spatial saturation pulses are selectively applied, they may be applied to other than the imaging areas or may be applied to within the imaging area so as to overlap partly or all.

Many widely different embodiments of the invention may be configured without departing from the spirit and the scope of the present invention. It should be understood that the present invention is not limited to the specific embodiments described in the specification, except as defined in the appended claims.

1. A magnetic resonance imaging apparatus which executes a mask scan for acquiring, as mask data, magnetic resonance signals produced in an imaging area in which a fluid flows through a subject, in a state in which a contrast agent is not injected into the fluid, and an imaging scan for acquiring, as imaging data, magnetic resonance signals produced in the imaging area in which the fluid containing the contrast agent flows after the injection of the contrast agent into the fluid, so as to correspond to a TRICKS method, thereby sequentially generating images about the imaging area along a time base, said magnetic resonance imaging apparatus comprising:
a scan device which executes the mask scan and the imaging scan,
wherein upon execution of the mask scan, the scan device repeatedly executes scans for transmitting a spatial saturation pulse to a corresponding area containing the fluid flowing into the imaging area and thereafter sequentially acquiring the magnetic resonance signals as the mask data every time of repetition, so as to correspond to respective segments divided into plural form in a k space.

2. The magnetic resonance imaging apparatus according to claim 1, wherein the scan device executes the mask scan in such a manner that the directions of sequentially acquiring the magnetic resonance signals with respect to the respective segments as the mask data every time of repetition are faced in directions opposite to each other through the center of the k space at the segments.

3. The magnetic resonance imaging apparatus according to claim 2, wherein the scan device executes the mask scan in such a manner that the acquisition directions are faced from the center of the k space to its periphery.

4. The magnetic resonance imaging apparatus according to claim 1, wherein after the transmission of the spatial saturation pulse, the scan device further executes the mask scan so as to sequentially acquire the magnetic resonance signals as the mask data every time of repetition after the elapse of each time of repetition free of acquisition of the magnetic resonance signals as the mask data.

5. The magnetic resonance imaging apparatus according to claim 1, wherein upon execution of the mask scan, the scan device executes the scans in such a manner that they correspond to respective segments divided into plural form so as to be symmetric through an axis passing through the center of a k space.

6. The magnetic resonance imaging apparatus according to claim 1, wherein upon execution of the mask scan, the scan device executes the scans in such a manner that they correspond to respective segments divided into plural form so as to be radially symmetric from the center of a k space to its periphery.

7. The magnetic resonance imaging apparatus according to claim 1, wherein the scan device executes the mask scan before the execution of the imaging scan.

8. A magnetic resonance imaging method which executes a mask scan for acquiring, as mask data, magnetic resonance signals produced in an imaging area in which a fluid flows through a subject, in a state in which a contrast agent is not injected into the fluid, and an imaging scan for acquiring, as imaging data, magnetic resonance signals produced in the imaging area in which the fluid containing the contrast agent flows after the injection of the contrast agent into the fluid, so as to correspond to a TRICKS method, thereby sequentially generating images about the imaging area along a time base, said magnetic resonance imaging apparatus comprising a step of:
upon execution of the mask scan, repeatedly executing scans for transmitting a spatial saturation pulse to a corresponding area containing the fluid flowing into the imaging area and thereafter sequentially acquiring the magnetic resonance signals as the mask data every time of repetition, so as to correspond to respective segments divided into plural form in a k space.

9. The magnetic resonance imaging method according to claim 8, further comprising a step of:
executing the mask scan in such a manner that the directions of sequentially acquiring the magnetic resonance signals with respect to the respective segments as the mask data every time of repetition are faced in directions opposite to each other through the center of the k space at the segments.

10. The magnetic resonance imaging method according to claim 9, further comprising a step of:
executing the mask scan in such a manner that the acquisition directions are faced from the center of the k space to its periphery.

11. The magnetic resonance imaging method according to claim 8, wherein after the transmission of the spatial saturation pulse, the scan device executes the mask scan so as to sequentially acquire the magnetic resonance signals as the mask data every time of repetition after the elapse of each time of repetition free of acquisition of the magnetic resonance signals as the mask data.

12. The magnetic resonance imaging method according to claim 8, further comprising a step of:
upon execution of the mask scan, executing the scans in such a manner that they correspond to respective segments divided into plural form so as to be symmetric through an axis passing through the center of a k space.

13. The magnetic resonance imaging method according to claim 8, wherein upon execution of the mask scan, the scan device executes the scans in such a manner that they correspond to respective segments divided into plural form so as to be radially symmetric from the center of a k space to its periphery.

14. The magnetic resonance imaging method according to claim 8, wherein the scan device executes the mask scan before the execution of the imaging scan.

15. A magnetic resonance imaging apparatus which executes a mask scan for acquiring, as mask data, magnetic resonance signals produced in an imaging area of a subject, and an imaging scan for acquiring, as imaging data, magnetic resonance signals produced in the imaging area, so as to correspond to a TRICKS method, thereby sequentially generating images about the imaging area along a time base, said magnetic resonance imaging apparatus comprising:
a scan device which executes the mask scan and the imaging scan,
wherein upon execution of the mask scan, the scan device repeatedly executes scans for transmitting a preparation pulse to the subject and thereafter sequentially acquiring the magnetic resonance signals as the mask data every time of repetition, so as to correspond to respective segments divided into plural form in a k space.

16. The magnetic resonance imaging apparatus according to claim 15, wherein the scan device executes the mask scan in such a manner that the directions of sequentially acquiring the magnetic resonance signals with respect to the respective segments as the mask data every time of repetition are faced in directions opposite to each other through the center of the k space at the segments.

17. The magnetic resonance imaging apparatus according to claim 16, wherein the scan device executes the mask scan in such a manner that the acquisition directions are faced from the center of the k space to its periphery.

18. A magnetic resonance imaging method which executes a mask scan for acquiring, as mask data, magnetic resonance signals produced in an imaging area of a subject, and an imaging scan for acquiring, as imaging data, magnetic resonance signals produced in the imaging area, so as to correspond to a TRICKS method, thereby sequentially generating images about the imaging area along a time base, said magnetic resonance imaging method comprising the step of:
upon execution of the mask scan, repeatedly executing scans for transmitting a preparation pulse to the subject and thereafter sequentially acquiring the magnetic resonance signals as the mask data every time of repetition, so as to correspond to respective segments divided into plural form in a k space.

19. The magnetic resonance imaging method according to claim 18, wherein the scan device executes the mask scan in such a manner that the directions of sequentially acquiring the magnetic resonance signals with respect to the respective segments as the mask data every time of repetition are faced in directions opposite to each other through the center of the k space at the segments.

20. The magnetic resonance imaging method according to claim 19, wherein the scan device executes the mask scan in such a manner that the acquisition directions are faced from the center of the k space to its periphery.
